(19) United States
(12) Patent Application Publication
(10) Pub. No.: US 2016/0293425 A1
(43) Pub. Date: Oct. 6, 2016

(54) METHOD FOR MANUFACTURING SEMICONDUCTOR SUBSTRATE

(71) Applicant: TOKYO OHKA KOGYO CO., LTD., Kawasaki-shi (JP)

(72) Inventor: Yoshihiro SAWADA, Kawasaki-shi (JP)

(21) Appl. No.: 15/085,657

(22) Filed: Mar. 30, 2016

(30) Foreign Application Priority Data
Apr. 3, 2015 (JP) 2015-076884
Mar. 9, 2016 (JP) 2016-046024

(51) Int. Cl. H01L 21/225; H01L 29/167; H01L 21/324

(52) U.S. Cl. CPC H01L 21/2254; H01L 21/324; H01L 29/167; H01L 29/66795

(57) ABSTRACT

A method for manufacturing a semiconductor substrate, including coating a diffusion agent composition containing an impurity diffusion ingredient on a semiconductor substrate, followed by heating the formed coating film to diffuse the impurity diffusion ingredient in the semiconductor substrate, so that the impurity diffusion ingredient can be well diffused into the semiconductor substrate by the coating of the diffusion agent composition in a nano-scale thickness and heat treatment for a short period of time. When a composition comprising an impurity diffusion ingredient and a silicon compound of a predetermined structure containing an isocyanate group as the diffusion agent composition is used, the diffusion agent composition is coated on the semiconductor substrate in a thickness of not more than 30 nm and the coating film of the diffusion agent composition is heated by a predetermined method for a short period of time.

This application is based on and claims the benefit of priority from Japanese Patent Application Nos. 2015-076884 and 2016-046024, respectively filed on 3 Apr. 2015 and 9 Mar. 2016, the contents of which are incorporated herein by reference.

### BACKGROUND OF THE INVENTION

1. Field of the Invention

The present invention relates to a method for manufacturing a semiconductor substrate, the method comprising coating a diffusion agent composition containing an impurity diffusion ingredient on a semiconductor substrate and then diffusing the impurity diffusion ingredient from the diffusion agent composition.

2. Related Art

Semiconductor substrates used in semiconductor elements such as transistors, diodes and solar batteries are manufactured by diffusing impurity diffusion ingredients such as phosphorus and boron into the semiconductor substrates.

An example of a method for manufacturing such semiconductor substrates known in the art comprises coating a diffusion agent composition containing an impunity diffusion ingredient such as an organic phosphorus compound, a polymer for thickening, an organic solvent, and water on a semiconductor substrate, and then heating the coating at a temperature above 1000° C. for a long period of time, for example, for 10 hour to diffuse the impurity diffusion ingredient into the semiconductor substrate (see Patent Document 1).

Patent Document 1: Japanese Unexamined Patent Application, Publication No. 2005-347306

### SUMMARY OF THE INVENTION

In the method described in Patent Document 1, however, heat treatment for a long period of time, for example, for 10 hour is carried out for the diffusion of the impurity diffusion ingredient, poses a problem of the productivity of semiconductor substrates. For this reason, a method for manufacturing a semiconductor substrate that the impurity diffusion ingredient can be diffused in the semiconductor substrate even in heat treatment for a short period of time has been desired.

Further, in some cases, the semiconductor substrate has a three-dimensional steric structure on a surface thereof. An example of the three-dimensional steric structure is a nano-scale three-dimensional structure like a steric structure for the formation of multigate elements called Fin-FETs, the steric structure comprising a plurality of source fins, a plurality of drain fins, and gates perpendicular to the fins.

In this case, in order to uniformly diffuse an impurity diffusion ingredient from a coating film of a diffusion agent composition in the surface of a semiconductor substrate, additional formation of a coating film having an uniform thickness, for example, also on the surface of side walls of concaves in the steric structure is desired. To this end, uniform coating of the diffusion agent composition in a nano-scale thickness on the whole substrate surface, as well as superior diffusion of the impurity diffusion ingredient from the thin coating film thus formed are necessary.

As disclosed in Patent Document 1, however, in a diffusion agent composition containing a polymer for thickening, it is difficult to uniformly coat the diffusion agent composition on a surface of a semiconductor substrate in a nano-scale thickness.

The present invention has been made in view of the above problems, and an object of the present invention is to provide a method for manufacturing a semiconductor substrate, the method comprising coating a diffusion agent composition containing an impurity diffusion ingredient on a semiconductor substrate and heating the formed coating film to diffuse the impurity diffusion ingredient in the semiconductor substrate, wherein the impurity diffusion ingredient can be well diffused into the semiconductor substrate by the coating of the diffusion agent composition in a nano-scale thickness and heat treatment for a short period of time.

The present inventors have found that, when a composition comprising an impurity diffusion ingredient (A) and a Si compound (B) containing an isocyanate group and having a predetermined structure is used as the diffusion agent composition, the impurity diffusion ingredient can be well diffused from the coating film into the semiconductor substrate by coating the diffusion agent composition on the semiconductor substrate in a thickness of not more than 30 nm and heating the coating film of the diffusion agent composition by a predetermined method for a short period of time.

Specifically, the present invention relates to

a method for manufacturing a semiconductor substrate, the method comprising: forming a coating film having a thickness of not more than 30 nm by coating a diffusion agent composition onto a semiconductor substrate; and

diffusing an impurity diffusion ingredient (A) contained in the diffusion agent composition into the semiconductor substrate, wherein

the diffusion agent composition comprises the impurity diffusion ingredient (A) and an Si (silicon) compound (B) represented by the following formula (1), and

the diffusion of the impurity diffusion ingredient (A) is carried out by one or more methods selected from the group consisting of lamp annealing methods, laser annealing methods, and microwave irradiation methods:

R₄₋ₙSi(NCO)ₙ (1)

wherein R represents a hydrocarbon group; and n is an integer of 3 or 4.

The present invention can provide a method for manufacturing a semiconductor substrate, the method comprising coating a diffusion agent composition containing an impurity diffusion ingredient on a semiconductor substrate and heating the formed coating film to diffuse the impurity diffusion ingredient into the semiconductor substrate, wherein the impurity diffusion ingredient can be well diffused into the semiconductor substrate by the coating of the diffusion agent composition in a nano-scale thickness and heat treatment for a short period of time.

### DETAILED DESCRIPTION OF THE PREFERRED EMBODIMENTS

The method for manufacturing a semiconductor substrate according to the present invention comprises a coating step of forming a coating film having a thickness of not more than 30 nm by coating a diffusion agent composition onto a semiconductor substrate and a diffusion step of diffusing a impurity diffusion ingredient (A) contained in the diffusion agent composition into the semiconductor substrate. The diffusion agent composition comprises an impurity diffusion ingredient (A) and a Si compound (B) represented by the following formula (1):

R₄₋ₙSi(NCO) (1)

wherein R represents a hydrocarbon group; and n is an integer of 3 or 4.

Next, the coating step and the diffusion step will be described hereinafter in that order.

### <<Coating Step>>

In the coating step, a diffusion agent composition is applied onto a semiconductor substrate to form a coating film having a thickness of not more than 30 nm. For the coating step, diffusion agent compositions, semiconductor substrates, and coating methods will be described in order.

### <<Diffusion Agent Composition>>

The diffusion agent composition comprises an impurity diffusion ingredient (A) and a Si compound (B) represented by the following formula (1). In the present specification, the Si compound (B) is referred to also as a hydrolyzable silane compound (B). Indispensable or optional ingredients contained in the diffusion agent composition and a method for preparing the diffusion agent composition will be described.

### [Impurity Diffusion Ingredient (A)]

The impurity diffusion ingredient (A) is not particularly limited as long as the ingredient is one that has hitherto been used for doping of semiconductor substrates. The impurity diffusion ingredient (A) may be either an n-type dopant or a p-type dopant. Elementary substances such as phosphorus, arsenic, and antimony and compounds containing these elements may be mentioned as the n-type dopant. Elementary substances such as boron, gallium, indium, and aluminum and compounds containing these elements may be mentioned as the p-type dopant.

The impurity diffusion ingredient (A) is preferably a phosphorus compound, a boron compound, or an arsenic compound from the viewpoints of easy availability and easy handleability. Preferred phosphorus compounds include phosphoric acid, phosphorous acid, hypophosphorous acid, polyphosphoric acid, and diphosphorus pentaoxide, phosphorous acid esters, phosphoric acid esters, phosphorous acid tris(trialkylsilyl), and phosphoric acid tris(trialkylsilyl). Preferred boron compounds include boric acid, metaboric acid, boronic acid, perboric acid, hypoboric acid, diboron trioxide, and trialkyl borate. Preferred arsenic compounds include arsenic acid and trialkyl arsenate.

Preferred phosphorus compounds include phosphorous acid esters, phosphoric acid esters, tris(trialkylsilyl) phosphite, and tris(trialkylsilyl) phosphate. Among these, trimethyl phosphate, triethyl phosphate, trimethyl phosphite, triethyl phosphite, tris(trimethoxysilyl) phosphate, and tris(trimethoxysilyl) phosphite are preferred. Trimethyl phosphate, trimethyl phosphite, and tris(trimethylsilyl) phosphate are more preferred, and trimethyl phosphate is particularly preferred.

Trimethylboron, triethylboron, trimethyl borate, and triethyl borate are preferred as the boron compound.

Preferred arsenic compounds include arsenic acid, triethoxyarsenic, and tri-n-butoxyarsenic.

The content of the impurity diffusion ingredient (A) in the diffusion agent composition is not particularly limited. The content of the impurity diffusion ingredient (A) in the diffusion agent composition is such that the amount (moles) of elements that act as a dopant in a semiconductor substrate such as phosphorus, arsenic, antimony, boron, gallium, indium, and aluminum contained in the impurity diffusion ingredient (A) is preferably 0.01 to 5 times, more preferably 0.05 to 3 times, of the number of moles of Si contained in the hydrolyzable silane compound (B).

### [Hydrolyzable Silane Compound (B)]

The diffusion agent composition contains a hydrolyzable silane compound (B). The hydrolyzable silane compound (B) is a compound represented by the following formula (1):

R₄₋ₙSi(NCO)ₙ (1)

wherein R represents a hydrocarbon group; and n is an integer of 3 or 4.

By virtue of this constitution, when the diffusion agent composition is applied onto a semiconductor substrate to form a thin film, the hydrolyzable silane compound is subjected to hydrolysis condensation to form a silicon oxide-based very thin film within the coating film. When the silicon oxide-based very thin film is formed within the coating film, external diffusion of the impurity diffusion ingredient (A) on the outside of the substrate is suppressed. In this case, even when the film of the diffusion agent composition is a thin film, the impurity diffusion ingredient (A) is diffused well and uniformly into the semiconductor substrate.

The hydrocarbon group as R in the formula (1) is not particularly limited as long as the object of the present invention is not impeded. Aliphatic hydrocarbon groups having 1 to 12 carbon atoms, aromatic hydrocarbon groups having 1 to 12 carbon atoms, and aralkyl groups having 1 to 12 carbon atoms are preferred as R.

Examples of suitable aliphatic hydrocarbon groups having 1 to 12 carbon atoms include methyl, ethyl, n-propyl, isopropyl, n-butyl, sec-butyl, isobutyl, tert-butyl, n-pentyl, isopentyl, neopentyl, cyclopentyl, n-hexyl, cyclohexyl, n-heptyl, cycloheptyl, n-octyl, cyclooctyl, n-nonyl, n-decyl, n-undecyl, and n-dodecyl groups.

Examples of suitable aromatic hydrocarbon groups having 1 to 12 carbon atoms include phenyl, 2-methylphenyl, 3-methylphenyl, 4-methylphenyl, 2-ethylphenyl, 3-ethylphenyl, 4-ethylphenyl, α-naphthyl, β-naphthyl, and biphenylyl groups.

Examples of suitable aralkyl groups having 1 to 12 carbon atoms include benzyl, phenetyl, α-naphthylmethyl, β-naphthylmethyl, 2-α-naphthylethyl, and 2-β-naphthylethyl groups.

Among the above-described hydrocarbon atoms, methyl and ethyl groups are preferred, and a methyl group is more preferred.

Among the hydrolyzable silane compounds (B) represented by the formula (1), tetraisocyanatesilane, methyltriisocyanatesilane, and ethyltriisocyanatesilane are preferred, and tetraisocyanatesilane is more preferred.

The content of the hydrolyzable silane compound (B) in the diffusion agent composition is preferably 0.001 to 3.0% by mass, more preferably 0.01 to 1.0% by mass, in terms of Si concentration. When the diffusion agent composition contains the hydrolyzable silane compound (B) at this concentration, external diffusion of the impurity diffusion ingredient (A) from the thin coating film formed using the diffusion agent composition can be suppressed well and the impurity diffusion ingredient can be well diffused into the semiconductor substrate.

### [Organic Solvent (S)]

The diffusion agent composition usually contains an organic solvent (S) as a solvent for allowing formation of a thin coating film. The type of the organic solvent (S) is not particularly limited as long as the object of the present invention is not impeded.

The diffusion agent composition contains the hydrolyzable silane compound (B) and thus is preferably substantially free from water. The expression “the diffusion agent composition is preferably substantially free from water” means that the diffusion agent composition does not contain water in such an amount that the hydrolysis proceeds to a level that impedes the object of the present invention.

Specific examples of organic solvents (S) include sulfoxides such as dimethylsulfoxide; sulfones such as dimethylsulfone, diethylsulfone, bis(2-hydroxyethyl)sulfone, and tetramethylenesulfone; amides such as N,N-dimethylformamide, N-methylformamide, N,N-dimethylacetamide, N-methylacetamide, and N,N-diethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; (poly)alkylene glycol dialkyl ethers such as ethylene glycol dimethyl ether, ethylene glycol diethyl ether, diethylene glycol dimethyl ether, diethylene glycol methyl ether, diethylene glycol diethyl ether, and triethylene glycol dimethyl ether; (poly)alkylene glycol alkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers such as tetrahydrofuran; ketones such as methylethyl ketone, cyclohexanone, 2-heptanone, and 3-heptanone; lactic acid alkyl esters such as methyl 2-hydroxypropionate and ethyl 2-hydroxypropionate; other esters such as methyl 3-methoxypropionate, ethyl 3-methoxypropionate, methyl 3-ethoxypropionate, ethyl 3-ethoxypropionate, ethyl ethoxyacetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyrubate, ethyl pyrubate, n-propyl pyrubate, methyl acetoacetate, ethyl acetoacetate, and ethyl 2-oxobutanoate; lactones such as β-propylolactone, γ-butyrolactone, and δ-pentylolactone: linear, branched, or cyclic hydrocarbons such as n-hexane, n-heptane, n-octane, n-nonane, methyloctane, n-decane, n-undecane, n-dodecane, 2,2,4,6,6-pentamethylheptane, 2,2,4,4,6,8,8-heptamethylnonane, cyclohexane, and methylcyclohexane; aromatic hydrocarbons such as benzene, toluene, naphthalene, and 1,3,5-trimethylbenzene; and terpenes such as p-menthane, diphenylmenthane, limonene, terpinene, bornane, norbornane, and pinane. These organic solvents may be used solely or as a mixture of two or more of them.

Since the diffusion agent composition contains the hydrolyzable silane compound (B), organic solvents (S) free from functional groups reactive with the hydrolyzable silane compound (B) are preferred. In particular, when the hydrolyzable silane compound (B) contains an isocyanate group, the organic solvent (S) free from functional groups reactive with the hydrolyzable silane compound (B) is preferred.

Groups reactive with the hydrolyzable silane compound (B) include both of functional groups that react directly with groups capable of producing a hydroxyl group as a result of hydrolysis, and functional groups reactive with a hydroxyl group (a silanol group) as a result of hydrolysis. Functional groups reactive with the hydrolyzable silane compound (B) include, for example, hydroxyl, carboxyl, and amino groups as well as halogen atoms.

Examples of suitable organic solvents free from functional groups reactive with the hydrolyzable silane compound (B) include, among specific examples of the above organic solvents (S), organic solvents recited as specific examples of mono ethers, chain diethers, cyclic diethers, ketones, esters, amide solvents free from an active hydrogen atom, sulfoxides, aliphatic hydrocarbon-based solvents optionally containing halogens, and aromatic hydrocarbon-based solvents.

### [Other Ingredients]

The diffusion agent composition may contain various additives such as surfactants, antifoaming agents, pH adjustors, and viscosity modifiers as long as the object of the present invention is not impeded. Further, the diffusion agent composition may contain binder resins with a view to improving the coatability and film forming properties. Various resins may be used as the binder resin, and acrylic resins are preferred.

### [Process for Preparing Diffusion Agent Composition]

The diffusion agent composition can be prepared by mixing the above indispensable or optional ingredients together to prepare a homogeneous solution. In the preparation of the diffusion agent composition, the impurity diffusion ingredient (A) and the hydrolyzable silane compound (B) may be used as solutions of the impurity diffusion ingredient (A) and the hydrolyzable silane compound (B) that have previously been dissolved in organic solvents (S). The diffusion agent composition may if necessary be filtered through a filter having a desired opening diameter. Insoluble impurities are removed by the filtration treatment.

### <<Semiconductor Substrate>>

Various substrates that have hitherto been used as a target of diffusion of an impurity diffusion ingredient may be used as the semiconductor substrate without limitation. Silicon substrates are typically used as the semiconductor substrate.

The semiconductor substrate may have a three-dimensional structure on its surface onto which the diffusion agent composition is to be applied. According to the present invention, even when the semiconductor substrate has on its surface the three-dimensional structure, particularly a three-dimensional structure having a nano-scale micropattern, the impurity diffusion ingredient can be diffused well and uniformly into the semiconductor substrate by coating the diffusion agent composition to form a thin coating film having a thickness of not more than 30 nm on the semiconductor substrate.

The shape of the pattern is not particularly limited, however typical examples thereof include linear or curved lines or grooves of a rectangular cross section and hole shapes formed by removing a circular or rectangular cylindrical shape.

When the semiconductor substrate has on its surface a repeating pattern of a plurality of parallel lines as the three-dimensional structure, an interval between the lines may be not more than 60 nm, not more than 40 nm, or not more than 20 nm. The height of the lines may be not less than 30 nm, not less than 50 nm, or not less than 100 nm.

### <<Coating Method>>

The diffusion agent composition is applied onto the semiconductor substrate such that the thickness of the coating film formed using the diffusion agent composition is not more than 30 nm, preferably 0.2 to 10 nm. The method for coating the diffusion agent composition is not particularly limited as long as a coating film having a desired thickness can be formed. Preferred coating methods for the diffusion agent composition include spin coating, ink jet coating, and spray coating. The thickness of the coating film is an average of thickness values measured at five or more points with an ellipsometer.

The thickness of the coating film is properly set to any desired thickness of not more than 30 nm depending upon the shape of the semiconductor substrate and an arbitrarily determined degree of diffusion of the impurity diffusion ingredient (A).

After the application of the diffusion agent composition onto the surface of the semiconductor substrate, the surface of the semiconductor substrate is preferably rinsed with an organic solvent. The thickness of the coating film can be made further uniform by rinsing the surface of the semiconductor substrate after the formation of the coating film. In particular, when the semiconductor substrate has on its surface a three-dimensional structure, the thickness of the coating film is likely to be thick at the bottom (stepped portion) of the three-dimensional structure. However, the thickness of the coating film can be made uniform by rinsing the surface of the semiconductor substrate after the formation of the coating film.

The above organic solvents that may be contained in the diffusion agent composition may be used as the organic solvent for rinsing.

### <<Diffusion Step>>

In the diffusion step, the impurity diffusion ingredient (A) contained in the thin coating film formed on the semiconductor substrate using the diffusion agent composition is diffused into the semiconductor substrate. Heating in the diffusion of the impurity diffusion ingredient (A) into the semiconductor substrate is carried out by one or more methods selected from the group consisting of lamp annealing methods, laser annealing methods, and microwave irradiation methods.

Lamp annealing methods include rapid thermal annealing methods and flash lamp annealing methods.

The rapid thermal annealing method is a method that includes raising the temperature of the surface of a semiconductor substrate coated with a diffusion agent composition to a diffusion temperature at a high temperature rise rate by heating with a lamp, then holding a predetermined diffusion temperature for a short period of time, and then rapidly cooling the surface of the semiconductor substrate.

The flash lamp annealing method is a heat treatment method that includes irradiating the surface of a semiconductor substrate with flash light using a xenon flash lamp or the like to raise the temperature of only the surface of the semiconductor substrate coated with a diffusion agent composition to a predetermined temperature in a short period of time.

The laser annealing method is a heat treatment method that includes irradiating the surface of a semiconductor substrate with various laser beams to raise the temperature of only the surface of the semiconductor substrate coated with a diffusion agent composition to a predetermined diffusion temperature in a very short period of time.

The microwave irradiation method is a heat treatment method that includes irradiating the surface of a semiconductor substrate with microwaves to raise the temperature of only the surface of the semiconductor substrate coated with a diffusion agent composition to a predetermined diffusion temperature in a very short period of time.

In the diffusion step, the diffusion temperature in the diffusion of the impurity diffusion ingredient is preferably 600˜1400° C., more preferably 800 to 1200° C. After the temperature of the substrate surface has reached a diffusion temperature, the diffusion temperature may be held for a desired period of time. Within such a range that the impurity diffusion ingredient is well diffused, the shorter the period of holding a predetermined diffusion temperature, the more preferable it would be.

In the diffusion step, the temperature rise rate at which the temperature of the substrate surface is heated to a desired diffusion temperature is preferably not less than 25° C./sec. The temperature rise rate is preferably as high as possible in such a range that the impurity diffusion ingredient is well diffused.

Furthermore, formation of a semiconductor element employing the semiconductor substrate manufactured by the method of the present invention may require high concentration diffusion of the impurity diffusion ingredient in a shallow region from the semiconductor substrate surface, depending on its structure.

In this case, in the above impurity diffusion method, a temperature profile of rapidly raising temperature of the substrate surface to a predetermined temperature, followed by rapidly cooling the semiconductor substrate surface is preferably adopted. The heat treatment employing such a temperature profile is called spike annealing.

In the spike annealing, time for holding at the predetermined diffusion temperature is preferably not more than 1 sec. The diffusion temperature is preferably 950 to 1050° C. By the spike annealing at such a diffusion temperature for such a holding time, the impurity diffusion ingredient can be well diffused in a shallow region from the semiconductor substrate surface.

According to the above-described method of the present invention, in a method for manufacturing a semiconductor substrate by coating a diffusion agent composition containing an impurity diffusion ingredient on a semiconductor substrate followed by diffusing the impurity diffusion ingredient from the diffusion agent composition, the coating of the diffusion agent composition in a nano-scale thickness and heat treatment for a short period of time allow superior diffusion of the impurity diffusion ingredient into the semiconductor substrate.

### EXAMPLES

The present invention is described more specifically hereafter with reference to Examples, which however should not be construed as limiting the present invention.

### Examples 1 to 14

The following materials were used as ingredients for diffusion agent compositions. Tri-n-butoxy arsenic (a 4 mass % solution of n-butyl acetate) was used as an impurity diffusion ingredient (A). Tetraisocyanate silane was used as a hydrolyzable silane compound (B).

n-Butyl Acetate was Used as an Organic Solvent (S).

The impurity diffusion ingredient (A), the hydrolyzable silane compound (B), and the organic solvent (S) were homogeneously mixed such that the total concentration of the impurity diffusion ingredient (A) and the hydrolyzable silane compound (B) was 0.6% by mass and the As/Si element ratio was 0.5, followed by filtering through a 0.2 μm pore diameter filter to thereby obtain a diffusion agent composition.

The diffusion agent composition was applied with a spin coater onto a surface of a silicon substrate having a flat surface (4 in., P type) to form a 4.5 nm-thick coating film.

After the formation of the coating film, treatment was carried out for the diffusion of the impurity diffusion ingredient by the following method.

First, the coating film was baked on a hot plate. Subsequently, the film was heated in a nitrogen atmosphere at a flow rate of 1 L/m at a temperature rise rate of 25° C./sec, using a rapid thermal annealing apparatus (a lamp annealing apparatus), to thereby diffuse under the impurity diffusion conditions specified in Table 1. The start point of the holding time specified in Table 1 is a point at which the substrate temperature reached a predetermined diffusion temperature. After the completion of the diffusion, the semiconductor substrate was rapidly cooled to room temperature.

Under conditions of respective Examples, the surface As concentration (atoms/cm²) and diffusion depth of the substrates subjected to impurity diffusion treatment were measured with a quadrupolar secondary ion mass spectroscopic analyzer (Q-SIMS). The diffusion depth is such a depth from the semiconductor substrate surface that the amount of As after diffusion is 1.0E+14 (atoms/cc). The measurement results are shown in Table 1.

TABLE 1

| | Conditions | | | |
|---|---|---|---|---|
| | for | | | |
| | diffusion | | | |
| | treatment | | Surface | |
| | Temp. | Holding time | As concentration | Diffusion depth |
| | (° C.) | (Sec.) | (atoms/cm²) | (nm) |
| Ex. 1 | 1000 | 2 | 3.0E+14 | 39.5 |
| Ex. 2 | 1000 | 10 | 4.8E+14 | 67.3 |
| Ex. 3 | 1000 | 30 | 4.9E+14 | 81.6 |
| Ex. 4 | 1050 | 2 | 4.3E+14 | 59.2 |
| Ex. 5 | 1050 | 10 | 4.9E+14 | 72.4 |
| Ex. 6 | 1050 | 30 | 5.3E+14 | 95.4 |
| Ex. 7 | 1100 | 2 | 5.6E+14 | 96.6 |
| Ex. 8 | 1100 | 30 | 7.2E+14 | 146 |
| Ex. 9 | 1200 | 2 | 6.5E+14 | 201 |
| Ex. 10 | 900 | 2 | 9.5E+13 | 11.4 |
| Ex. 11 | 950 | 2 | 3.0E+14 | 28.2 |
| Ex. 12 | 1000 | 0.1 | 4.4E+14 | 27.1 |
| Ex. 13 | 1000 | 1 | 4.6E+14 | 30.5 |
| Ex. 14 | 950 | 1 | 2.1E+14 | 14.5 |

Table 1 shows that, in the case of forming a coating film having a thickness of not more than 30 nm by using a diffusion agent composition containing the hydrolyzable silane compound (B) represented by formula (1), the impurity diffusion ingredient is well diffused in the semiconductor substrate by a method involving heating in a short period of time, such as a lamp annealing method (a rapid thermal annealing method).

Table 1 also shows that the shorter holding time during the impurity diffusion results in the higher concentration diffusion of impurity diffusion ingredient at a shallower position from the substrate surface. As is apparent from Table 1, in the case of contemplating the high concentration and shallow diffusion of the impurity diffusion ingredient, the impurity diffusion ingredient is preferably diffused at a temperature of approximately 950 to 1050° C. for a very short period of not more than 5 sec.

### Examples 15 to 18

The following materials were used as ingredients of the diffusion agent composition. Tri-n-butoxy arsenic (a 4 mass % solution of n-butyl acetate) was used as the impurity diffusion ingredient (A). Methyltetraisocyanatesilane was used as the hydrolyzable silane compound (B).

n-Butyl Acetate was Used as the Organic Solvent (S).

The impurity diffusion ingredient (A), the hydrolyzable silane compound (B), and the organic solvent (S) were homogeneously mixed such that the total concentration of the impurity diffusion ingredient (A) and the hydrolyzable silane compound (B) was 0.38% by mass and the As/Si element ratio was 0.77, followed by filtering through a 0.2 μm pore diameter filter to thereby obtain a diffusion agent composition.

The above diffusion agent composition was coated on a surface of a silicon substrate having a flat surface (4-inch, p-type) with a spin coater to form a coating film of a thickness specified in Table 2.

Following the coating film formation, the diffusion treatment of the impurity diffusion ingredient was carried out according to the following method.

First, the coating film was baked on a hot plate. Subsequently, the film was heated in a nitrogen atmosphere at a flow rate of 1 L/m at a temperature rise rate of 25° C./sec with a rapid thermal annealing apparatus (a lamp annealing apparatus), to thereby diffuse under impurity diffusion conditions specified in Table 2. The start point of the holding time specified in Table 2 is a point at which the substrate temperature reached a predetermined diffusion temperature. After the completion of the diffusion, the semiconductor substrate was rapidly cooled to room temperature.

Under conditions of respective Examples, the surface As concentration (atoms/cm²) and diffusion depth of the substrates subjected to impurity diffusion treatment were measured with a quadrupolar secondary ion mass spectroscopic analyzer (Q-SIMS). The diffusion depth is such a depth from the semiconductor substrate surface that the amount of As after diffusion is 1.0E+17 (atoms/cc). The measurement results are shown in Table 1.

TABLE 2

| | | Conditions | | | |
|---|---|---|---|---|---|
| | | for | | | |
| | | diffusion | | | |
| | | treatment | | Surface | |
| | Thickness of | | Holding | As | Diffusion |
| | coating film | Temp. | time | concentration | depth |
| | (nm) | (° C.) | (Sec.) | (atoms/cm²) | (nm) |
| Ex. 15 | 1.3 | 1000 | 1 | 4.2E+13 | 11.5 |
| Ex. 16 | 1.3 | 1000 | 0.1 | 4.9E+13 | 11.1 |
| Ex. 17 | 0.6 | 1000 | 1 | 9.0E+12 | 8.1 |
| Ex. 18 | 0.6 | 1000 | 0.1 | 1.2E+13 | 8.3 |

As is apparent from Examples 15 to 18, even in the case of using methyltriisocyanatesilane instead of tetraisocyanate silane used in Examples 1 to 14 as the hydrolyzable silane compound (B), in forming a coating film having a thickness of not more than 30 nm using the diffusion agent composition, the impurity diffusion ingredient is well diffused in the semiconductor substrate by a method involving heating in a short period of time, such as a lamp annealing method (a rapid thermal annealing method).

### Examples 19 to 40

Compounds specified in Table 3 were used as the impurity diffusion ingredient (A) and the hydrolyzable silane compound (B).

n-Butyl Acetate was Used as the Organic Solvent (S).

The impurity diffusion ingredient (A) and the hydrolyzable silane compound (B) were homogeneously mixed such that the total concentration of the impurity diffusion ingredient (A) and the hydrolyzable silane compound (B) was as specified in Table 3 and the P/Si element ratio was as specified in Table 3, followed by filtering through a 0.2 μm pore diameter filter to thereby obtain a diffusion agent composition.

In Table 3, reference symbols for the impurity diffusion ingredient (A) (ingredient (A)) are as follows.

A1: tris(trimethylsilyl) phosphite
A2: tris(trimethylsilyl) phosphate
A3: trimethyl phosphate

In Table 3, reference symbols for the hydrolyzable silane compound (B) (ingredient (B)) are as follows.

B1: tetraisocyanate silane
B2: methyltriisocyanatesilane

The above diffusion agent composition was coated on a surface of a silicon substrate having a flat surface (4-inch, p-type) with a spin coater to form a coating film of a thickness specified in Table 3.

Following the coating film formation, the diffusion treatment of the impurity diffusion ingredient was carried out according to the following method.

First, the coating film was baked on a hot plate. Subsequently, the film was heated in a nitrogen atmosphere at a flow rate of 1 L/m at a temperature rise rate of 25° C./sec with a rapid thermal annealing apparatus (a lamp annealing apparatus), to thereby diffuse under impurity diffusion conditions specified in Table 3. The start point of the holding time specified in Table 3 is a point at which the substrate temperature reached a predetermined diffusion temperature. After the completion of the diffusion, the semiconductor substrate was rapidly cooled to room temperature.

Under conditions of respective Examples, the surface P concentration (atoms/cm²) and diffusion depth of the substrates subjected to impurity diffusion treatment were measured with a quadrupolar secondary ion mass spectroscopic analyzer (Q-SIMS). The diffusion depth is such a depth from the semiconductor substrate surface that the amount of P after diffusion is 1.0E+17 (atoms/cc). The measurement results are shown in Table 3.

TABLE 3

| | Diffusion agent | | | | | Conditions | | | |
|---|---|---|---|---|---|---|---|---|---|
| | composition | | | | | for diffusion | | | |
| | | | Total conc. | Element | Thickness of | treatment | | Surface P | Diffusion |
| | Ingredient | | (% by | ratio of | coating film | Temp. | Holding time | concentration | depth |
| | (A) | (B) | mass) | P/Si | (nm) | (° C.) | (Sec.) | (atoms/cm²) | (nm) |
| Ex. 19 | A1 | B1 | 0.47 | 0.454 | 5.4 | 900 | 5 | 2.0E+12 | 13.0 |
| Ex. 20 | A1 | B1 | 0.47 | 0.454 | 5.4 | 1000 | 7 | 7.0E+12 | 37.3 |
| Ex. 21 | A1 | B1 | 0.47 | 0.454 | 5.4 | 1100 | 10 | 3.3E+13 | 111 |
| Ex. 22 | A1 | B2 | 0.43 | 0.454 | 5.6 | 900 | 5 | 3.0E+12 | 20.5 |
| Ex. 23 | A1 | B2 | 0.43 | 0.454 | 5.6 | 1000 | 7 | 1.5E+13 | 35.7 |
| Ex. 24 | A1 | B2 | 0.43 | 0.454 | 5.6 | 1100 | 10 | 3.2E+13 | 102 |
| Ex. 25 | A2 | B2 | 0.44 | 0.454 | 5.0 | 900 | 5 | 5.0E+12 | 19.9 |
| Ex. 26 | A2 | B2 | 0.44 | 0.454 | 5.0 | 1000 | 7 | 3.1E+13 | 38.4 |
| Ex. 27 | A2 | B2 | 0.44 | 0.454 | 5.0 | 1100 | 10 | 8.1E+13 | 91.6 |
| Ex. 28 | A3 | B1 | 0.46 | 0.907 | 0.6 | 1100 | 10 | 7.0E+11 | 7.52 |
| Ex. 29 | A2 | B2 | 0.44 | 0.454 | 4.3 | 900 | 5 | 2.0E+12 | 15.2 |
| Ex. 30 | A2 | B2 | 0.44 | 0.454 | 4.3 | 1000 | 7 | 2.3E+13 | 35.5 |
| Ex. 31 | A2 | B2 | 0.44 | 0.454 | 4.3 | 1100 | 10 | 6.7E+13 | 90.9 |
| Ex. 32 | A2 | B1 | 0.31 | 0.635 | 2.3 | 900 | 5 | 2.0E+12 | 13.7 |
| Ex. 33 | A2 | B1 | 0.31 | 0.635 | 2.3 | 1000 | 7 | 1.8E+13 | 29.5 |
| Ex. 34 | A2 | B1 | 0.31 | 0.635 | 2.3 | 1100 | 10 | 7.0E+13 | 89.4 |
| Ex. 35 | A2 | B2 | 0.44 | 0.454 | 4.3 | 1000 | 1 | 3.9E+13 | 42.4 |
| Ex. 36 | A2 | B2 | 0.44 | 0.454 | 4.3 | 1000 | 0.1 | 4.8E+13 | 42.7 |
| Ex. 37 | A2 | B2 | 0.44 | 0.454 | 4.3 | 1100 | 0.1 | 1.1E+14 | 77.5 |
| Ex. 38 | A2 | B1 | 0.31 | 0.635 | 2.3 | 1000 | 1 | 2.8E+13 | 38.7 |
| Ex. 39 | A2 | B1 | 0.31 | 0.635 | 2.3 | 1000 | 0.1 | 2.7E+13 | 31.0 |
| Ex. 40 | A2 | B1 | 0.31 | 0.635 | 2.3 | 1100 | 0.1 | 6.1E+13 | 65.1 |

As is apparent from Examples 19 to 40, even in the case of using a phosphorus compound as the impurity diffusion ingredient, in forming a coating film with a thickness of not more than 30 nm using a hydrolyzable silane compound (B) represented by formula (1), the impurity diffusion ingredient is well diffused in the semiconductor substrate by a method involving heating in a short period of time, such as a lamp annealing method (a rapid thermal annealing method).

What is claimed is:

1. A method for manufacturing a semiconductor substrate, comprising:
forming a coating film having a thickness of not more than 30 nm by coating a diffusion agent composition onto a semiconductor substrate; and
diffusing an impurity diffusion ingredient (A) contained in the diffusion agent composition into the semiconductor substrate, wherein
the diffusion agent composition comprises the impurity diffusion ingredient (A) and an Si (silicon) compound (B) represented by the following formula (1), and
the diffusion of the impurity diffusion ingredient (A) is carried out by one or more methods selected from the group consisting of a lamp annealing method, a laser annealing method, and a microwave irradiation method:
R₄₋ₙSi(NCO)ₙ (1)
wherein R represents a hydrocarbon group; and n is an integer of 3 or 4.

2. The method for manufacturing a semiconductor substrate according to claim 1, wherein the impurity diffusion ingredient (A) is diffused by the lamp annealing method.

3. The method for manufacturing a semiconductor substrate according to claim 1, wherein the thickness of the coating film is 0.2 to 10 nm.
